(19) United States
(12) Patent Application Publication
(10) Pub. No.: US 2007/0183868 A1
(43) Pub. Date: Aug. 9, 2007

(54) Wafer transfer robot and semiconductor device manufacturing equipment comprising the same

(76) Inventor: Suck-woon Son, Hwaseong-si (KR)

Correspondence Address: VOLENTINE & WHITT PLLC, ONE FREEDOM SQUARE, 11951 FREEDOM DRIVE SUITE 1260, RESTON, VA, 20190, US

(21) Appl. No.: 11/507,567

(22) Filed: Aug. 22, 2006

(30) Foreign Application Priority Data
Feb. 6, 2006 (KR) 2006-0011261

(51) Int. Cl. H01L 21/677

(52) U.S. Cl. 414/217

(57) ABSTRACT

A wafer transfer robot for use in multi-chambered semiconductor device manufacturing equipment includes a base, at least one extendable and retractable arm rotatably supported by the base at one side thereof, and a blade coupled to the other side of each arm. The blade includes a plate having an upper surface dedicated to support a wafer, and a wafer guide disposed at the top of the plate. The wafer seats a wafer on the plate and confines the wafer to an orientation in which a flat zone or notch of the wafer faces in a predetermined direction. Therefore, the wafer can be prevented from slipping to an abnormal position on the blade and a pre-alignment of the wafer can be maintained. Thus, the wafer transfer robot helps to sustain the production yield.

### BACKGROUND OF THE INVENTION

1. Field of the Invention

The present invention relates to semiconductor device manufacturing equipment. More particularly, the present invention relates to multi-chambered semiconductor device manufacturing equipment and to a wafer transfer robot for transferring a wafer between chambers of the equipment.

2. Description of the Related Art

Semiconductor devices are being constantly developed along with the rapid development of information telecommunications technology and the increase in popularity of information processing devices such as personal computers. In this respect, today's semiconductor devices must operate at high speeds and have the capacity to store large amounts of data. Thus, techniques in the fabricating of semiconductor devices are being studied and developed with an aim toward maximizing the integration density, reliability, and response speed, etc., of the devices.

In general, a semiconductor device has several thin layers of circuit patterns stacked on a pure silicon wafer. A plurality of individual processes, such as thin film deposition, photolithography, ashing, etching, and ion implantation processes are repetitively and sequentially performed on the wafer to fabricate the circuit patterns. In general, these sequences of processes are performed in two different ways. One way is batch (or multi-wafer) processing in which several wafers are processed at the same time. The other way is single-wafer processing in which wafers are processed one at a time.

Batch processing provides a high throughput because about up to 50 wafers can be processed at a time. On the other hand, single-wafer processing is generally more time consuming but allows for each process to be carried out very precisely. However, multi-chamber semiconductor device manufacturing equipment has been developed to carry out single-wafer processing with high throughput.

Typical multi-chamber semiconductor device manufacturing equipment comprises at least one process chamber in which an ion implantation or etching process is performed, a transfer chamber that communicates with the process chamber, a wafer transfer robot disposed in the transfer chamber, a load-lock chamber that is mounted on one side of the transfer chamber and into which a plurality of wafers are loaded and unloaded en bloc, and an alignment chamber that communicates with the transfer chamber and aligns the wafers for their transfer by the transfer robot.

The wafer transfer robot rapidly and sequentially transfers individual wafers between the load-lock chamber, the alignment chamber, and the process chamber so that the multi-chamber semiconductor device manufacturing equipment can provide a high throughput even though the wafers are each processed one at a time in the process chamber(s), i.e., even though the equipment carries out single-wafer processing.

The wafer transfer robot of the conventional semiconductor device manufacturing equipment includes a body that is supported on the ground and has a rotary drive unit, an arm coupled on one side thereof to the body so as to be rotated by the rotary drive unit, and at least one blade disposed on the other end of the arm. The arm is made up of links that are articulated such that the arm can be extended and retracted with respect to the body. Thus, the arm moves the blade forward or backward when the arm is extended or retracted. Furthermore, the blade includes a metallic plate oriented to support a wafer horizontally. More specifically, the metallic plate has the shape of a fork comprising at least one prong. The fork is longer than the diameter of the wafer supported by the blade. Accordingly, the blade supports the center of the wafer.

Furthermore, the blade has an arcuate wafer guide step which extends along part of the outer peripheral edge of the blade and protrudes a predetermined height from the surface of the blade on which the wafer rests. The wafer guide step extends around enough of the wafer to prevent the wafer from sliding in a horizontal direction while the wafer is being transferred. For example, the wafer guide step confronts the outer circumferential surface of the wafer at the side of the blade coupled to the arm and at the distal end of the blade, i.e., at the tip(s) of the prong(s). Furthermore, the wafer guide step has an inclined inner side surface that guides a wafer loaded onto the blade and seats the wafer on the blade.

However, the wafer mounted on the blade gains inertia when the blade is rapidly rotated or moved forward or backward by the arm. In addition, the coefficient of friction between the wafer and the blade is low because the blade is metallic. Consequently, the wafer slides up along the inclined surface of the wafer guide step when the blade stops rotating or moving, thereby falling off of the blade or assuming an abnormal position on the blade. In either of these cases the wafer can be damaged, which reduces the production yield.

Furthermore, the wafer guide step has a radius of curvature equal or similar to that of the wafer in order to guide the outer circumferential surface of the wafer and seat the wafer on the blade. However, the wafer can rotate relative to the blade when the blade comes to a stop because, again, the coefficient of friction between the wafer and the blade is low. Thus, the wafer loses its alignment with the site or chuck (wafer support) disposed in the processing chamber to which the wafer is being transferred by the transfer robot. As a result, the wafer can be processed incorrectly, whereby the production yield is reduced.

### SUMMARY OF THE INVENTION

Therefore, an object of the present invention is to provide wafer transfer robot that does not adversely affect the production yield of a manufacturing process carried out by equipment that employs the wafer transfer robot.

A more specific object of the present invention is to provide a wafer transfer robot having a blade that includes a plate on which a wafer being transferred is supported, and which prevents a wafer supported by the blade from falling from the blade or from slipping to an abnormal position on the blade especially when the blade is rapidly rotated or accelerated in forward or backward directions.

Another object of the present invention is to provide a wafer transfer robot, in which a wafer does not slide or rotate relative to the blade, such that a wafer can be transferred to or from a designated position without its pre-aligned state being altered.

According to one aspect of the present invention, there is provided a wafer transfer robot which comprises a base, at least one extendable and retractable arm rotatably supported by the base at one side thereof, and a blade coupled to the other side of each said arm, wherein the blade includes a plate having an upper surface dedicated to support a wafer, and a wafer guide disposed at the top of the plate. The wafer guide has at least one guide surface projecting above the upper surface of the plate and which is complimentary to an arcuate edge and to either a flat zone or a notched portion of a wafer.

According to another aspect of the present invention, there is provided semiconductor device manufacturing equipment which comprises at least one load-lock, a wafer alignment apparatus that aligns wafers, at least one process apparatus, a transfer chamber to which each of the chambers of the load-lock, alignment and process apparatuses are commonly connected, and a wafer transfer robot disposed within the transfer chamber, wherein the wafer transfer robot includes a base, at least one arm coupled to the base at one side thereof, and a blade coupled to the other side of each arm, wherein the blade includes a plate having an upper surface dedicated to support a wafer, and a wafer guide disposed at the top of the plate. The wafer guide has at least one guide surface projecting above the upper surface of the plate and which is complimentary to an arcuate edge and to either a flat zone or a notched portion of a wafer.

Thus, the wafer guide is configured to confine a wafer supported on the plate to an orientation in which a flat zone or notch of the wafer faces in a predetermined direction. In particular, the wafer guide of the wafer transfer robot may include a wafer guide step having an arcuate vertical guide surface whose radius of curvature corresponds to that of a wafer, and a wafer orientation guide pin having a linear or pointed vertical guide surface that corresponds to a flat zone or notch of a wafer. The wafer orientation guide pin may also be mounted at an end of the plate so as to be rotatable about an axis extending perpendicular to the upper surface of the plate. Furthermore, the wafer orientation guide pin and the wafer guide step may each have an inclined guide surface that guides the wafer onto the plate when the wafer is lowered towards the blade. The blade may also include at least one pad at the upper surface of the plate so as to contact a lower surface of the wafer supported by the pate. The pad is of a material, such as rubber, which will provide a high coefficient of friction with the wafer.

### BRIEF DESCRIPTION OF THE DRAWINGS

The above and other objects, features and advantages of the present invention will become more apparent to those of ordinary skill in the art by referring to the following detailed description of the preferred embodiments thereof made with reference to the attached drawings in which:

FIG. 1 is a schematic plan view of semiconductor device manufacturing equipment according to the present invention;

FIG. 2 is a perspective view of the wafer transfer robot of the equipment shown in FIG. 1, according to the present invention;

FIG. 3 is a sectional view of the wafer transfer robot;

FIG. 4 is a broken away perspective view of the rotary driver of the wafer transfer robot; and

FIG. 5 includes side and plan views of the blade of the wafer transfer robot.

### DETAILED DESCRIPTION OF THE PREFERRED EMBODIMENTS

The present invention will now be described more fully hereinafter with reference to the accompanying drawings. Note, like numbers designate like elements throughout the drawings.

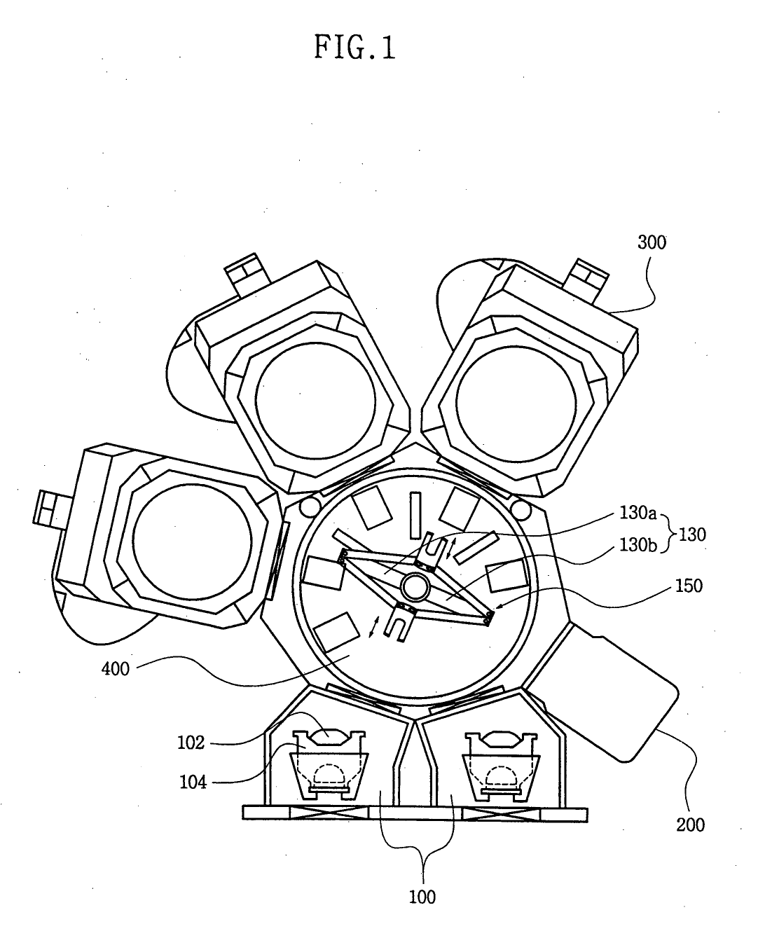

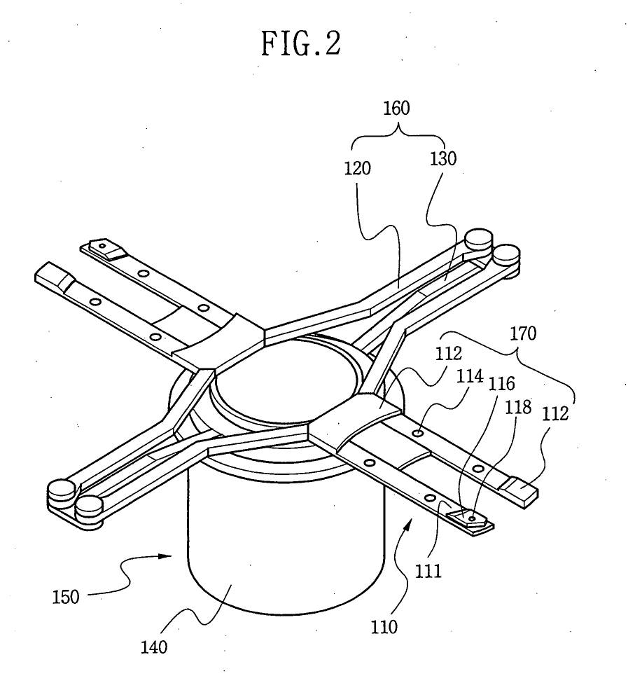

As illustrated in FIGS. 1 and 2, semiconductor device manufacturing equipment according to the present invention includes a plurality of load-locks 100 each comprising a chamber accommodating a cassette 104 in which a plurality of wafers 102 are mounted, an alignment apparatus 200 which aligns wafers 102 transferred from the load-lock chambers 100, at least one process apparatus 300 for performing a semiconductor device manufacturing process, a transfer chamber 400 to which the process apparatus 300, the alignment apparatus 200, and the load-locks 100 are commonly connected, and a wafer transfer robot 150 disposed in the transfer chamber 400. The wafer transfer robot 150 has at least one blade 110 that transfers a wafer 102 between the chambers of the load-lock and process apparatus 100 and 300.

For example, the wafer transfer robot 150 may have two blades 110 facing in opposite directions. Such a robot may be referred to hereinafter as a “two-blade wafer transfer robot”. The two-blade wafer transfer robot 150 transfers a wafer 102 aligned in the chamber of the alignment apparatus 200 to the front of a process chamber 300 using one blade 110, and transfers a wafer 102 that has been processed in a process chamber 300 into the chamber of a load-lock 100 using the other blade 110. On the other hand, the wafer transfer robot 150 may have only one blade 110. Such a wafer transfer robot will be referred to hereinafter as a “one-blade transfer robot”. The one-blade wafer transfer robot 150 first unloads a wafer 102 processed in the chamber of a process apparatus 300, and then transfers a wafer 102 aligned in the chamber of the alignment apparatus 200 to a process chamber 300. Accordingly, the one-blade wafer transfer robot 150 takes at least twice as long as the two-blade wafer transfer robot 150 to transfer an equal number of wafers 102 throughout corresponding pieces of the semiconductor device manufacturing equipment. Reference will be made with respect to a two-blade transfer robot in the description that follows.

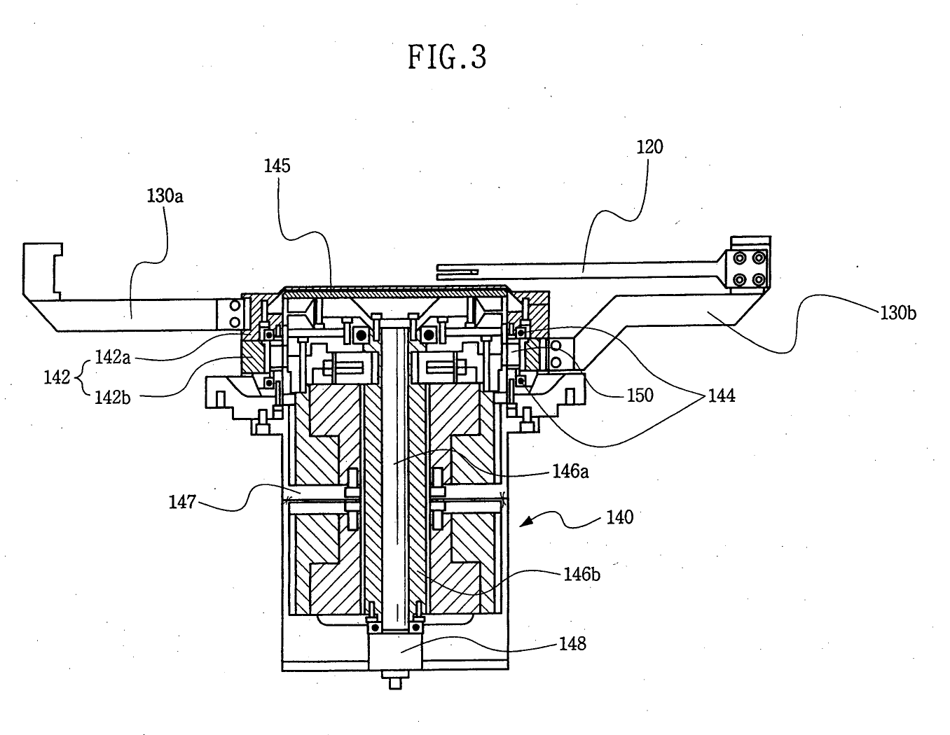

Referring now to FIG. 2 and FIG. 3, the wafer transfer robot 150 also has a base 140 that is supported on the ground, and a plurality of arms 160. The base 140 includes a tubular casing 147 and a rotary drive unit 148 disposed at the bottom of the casing 147. One side of each of the arms 160 is coupled to the body 140 so that the arms 160 can be rotated in their entirety by the rotary drive unit 148. Also, each of the arms 160 includes a pair of wings 130 having first ends coupled to the rotary drive unit 148, and a plurality of extenders 120. The extenders 120 of each arm 160 have first ends that are pivotally connected to second ends of the wings 130 of the arm 160, respectively. Second ends of the extenders 120 of each arm 160 are pivotally connected to a respective blade 110. The wings 130 of each arm 160 can be rotated relative to each other by the rotary drive unit 148 to move the blades 110 forward or backward. In particular, the extenders 120 move the blade 110 forward or backward when the wings 130 are rotated in opposite directions by the rotary drive unit 148.

For instance, the blades 110 are in a home position when the wings 130 of each arm 160 extend parallel to each other but in opposite directions from the body 140, as shown in FIG. 2. In this case, the blades 110 are moved forward from the home position, i.e., are extended from the body 140, when the wings 130 of each arm 160 are rotated at the same time toward one another. On the other hand, the blades 110 are moved backward when the wings 130 of each arm 160 are rotated at the same time away from each other.

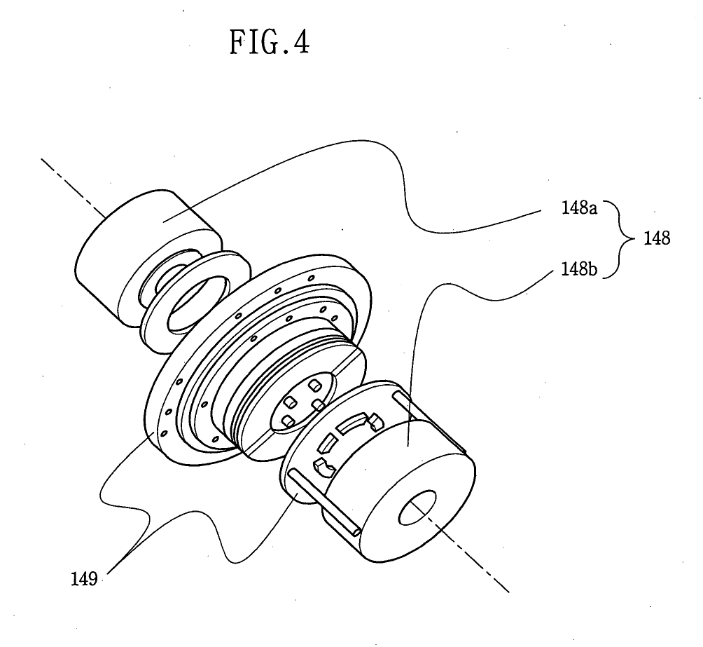

Next, the rotary drive unit 148 and its connection to the arms 160 will be described in more detail with reference to FIGS. 3 and 4.

The base 140 of the wafer transfer robot 150 has a plurality of rings 142, e.g., an upper ring 142a and a lower ring 142b, disposed one above the other on the base 140. The first ends of the two wings 130 of each arm 160 are attached to the rings 142a, 142b, respectively. That is, a first wing 130a of each arm 160 is attached to the upper ring 142a, and a second wing 130b of the arm is attached to the lower ring 142b. Also, the wings 130 have horizontal portions extending from the second ends thereof that are connected to the extenders 120. As shown best in FIG. 3, the horizontal portions of the wings 130 are situated at the same or similar level as the extenders 120. Moreover, one of the wings 130 of each arm 160 has a downward bend to account for the difference in height between the rings 142.

The rings 142 are supported by bearings 144 so as to be rotatable relative to the casing 147 of the base 140. The base 140 also includes a first shaft 146a for rotating the upper ring 142a, and a second shaft 146b for rotating the lower ring 142b. The second shaft 146b surrounds the first shaft 146a.

The rotary drive unit 148 includes a reversible upper motor 148a connected to the lower portion of the first shaft 146a for rotating the first shaft 146a, and a reversible lower motor 148b connected to the lower portion of the second shaft 146b for rotating the second shaft 146b. The upper and lower motors 148a and 148b are supported on a plurality of mounts 149 inside the casing 147, respectively. Each of the upper and lower motors 148a and 148b may be a stepping motor.

In addition, discs 145 are mounted to the first and second shafts 146a and 146b, respectively. Each disc 145 has permanent magnets spaced at predetermined intervals along the outer circumferential surface thereof. Each ring 142 has permanent magnets spaced along its inner circumferential surface. The inner and outer circumferential surfaces of the discs 145 and the rings 142 face each other, respectively. The magnetic fields of the permanent magnets are established in the rotational direction of the upper and lower rings 142a and 142b. Thus, the upper and lower rings 142a and 142b are rotated by magnetic forces when the first and second shafts 146a and 146b are rotated, respectively. Therefore, the upper and lower motors 142a and 142b of the wafer transfer robot 150 can be operated to rotate the wings 130 of each arm 160 in the same or different directions, thereby moving the blades 110 forward or backward via the extenders 120.

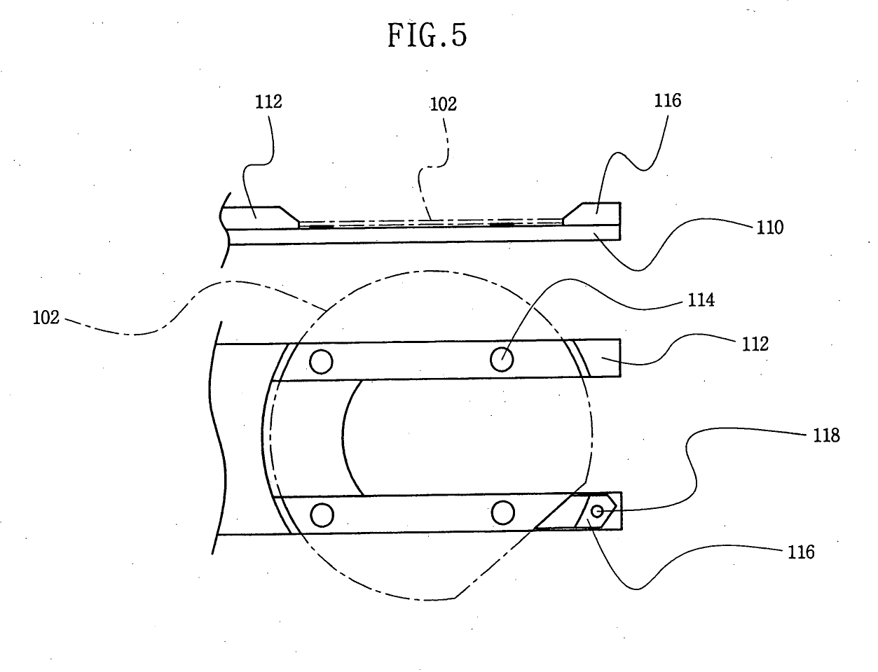

The blades 110 will now be described in more detail with reference to FIGS. 2 and 5. Each blade 110 includes a wafer support plate 111 formed of at least one member for supporting a wafer 102. The plate 111 has an upper (horizontal) surface parallel to the direction in which the extenders 120 and hence, the blades 110, move forward or backward. Each blade 110 also has a pivot (not shown), such as a pin, connecting the plate 111 to the second end of an extender 120, and a bearing (also not shown) interposed between the pin and the second end of the extender 120. Thus, the plate 111 can rotate relative to the second ends of the extenders 120 when the extenders 120 are moved forward or backward.

The shape of the plate 111 is such as to support the wafer 102 symmetrically about the center of the wafer 102 (the wafer may have a flat zone or notch at or in one side of the wafer 102 and thus, the center of the wafer may not coincide with the geometrical center of the circular outline of the wafer 102). For example, the plate 111 can have the shape of a palm that supports the center of the wafer 102. In this case, there is only a slight possibility that the wafer 102 will slide relative to the plate 111 because of the wide area of contact between the lower surface of the wafer 102 and the plate 111. Alternatively, the plate 111 can have the shape of a fork having prongs supporting the wafer 102 at both sides of the center of the wafer 102. In this case, the plate 111 allows the blade 110 to move forward or backward when lift pins (not shown) are used to remove or the wafer from or transfer the wafer onto the blade 110. Such lift pins are commonly found in the wafer support of a process apparatus. The lift pins can be inserted between the prongs into contact with the lower surface of the wafer 102. Then, the blade 110 can be moved backward so that the wafer 102 can be transferred from the blade 110 to the lift pins while maintaining its horizontal orientation. The unloading of a wafer 102 from the blade 110, the loading of a wafer 102 onto the blade 100, and the transferring of a wafer 102 by the blade 110 can all be carried out stably because the blade supports a wafer with its center located at the geometrical center of the plate 111 of the blade 110.

In any case, the wafer transfer robot 150 must be operated below a certain speed if a wafer 102 being transferred is to be stably and accurately in loaded or unloaded into or from a chamber of the equipment. That is, a wafer 102 supported on the blade 110 would attempt to rotate or slide relative to the wafer support plate 111 under its own inertia when the blade 110 accelerates. If this were allowed to occur, the orientation of the wafer would change, i.e., the pre-alignment of the wafer 102 would be ruined.

However, each blade 110 of the wafer transfer robot 150 according to the present invention has a wafer guide 170 that fixes the wafer 102 in place in a predetermined orientation on the wafer support plate 111. In particular, the wafer guide 170 cooperates with a flat zone or notch at or in the edge of the wafer 102 prevent the wafer 120 from sliding relative to the wafer support plate 111 and thereby maintain the orientation (alignment) of the wafer.

The wafer guide 170 will now be described in more detail with reference to FIGS. 2 and 5. The wafer guide 170 includes a wafer guide step 112 having a vertical arcuate surface protruding upwardly from the plate 111 around a portion of the wafer 102 to seat the wafer 102 on the plate 111 at a position where the center of the wafer 102 coincides with the center of the plate 111, and an inclined guide surface extending to the arcuate vertical surface so as to guide the wafer 112 into position on the plate 111. Furthermore, the wafer guide step 112 prevents the wafer 102 supported on the plate 111 from sliding horizontally relative to the plate 111 while the wafer is being transferred.

In addition, the blade 110 includes at least one pad 114 disposed on the plate 111 so as to contact the lower surface of a wafer 102 supported on the plate 111. The at least one pad 114 has a higher coefficient of friction with the wafer 102 than the plate 111. For example, the pad 114 is formed of rubber. In the embodiment of FIGS. 2 and 5, four pads 114 are formed on the prongs of the plate 111 and can prevent the wafer 102 from sliding in any direction relative to the plate 111.

Thus, the wafer transfer robot 150 according to the present invention can prevent a wafer 102 supported on the plate 111 from escaping from the blade 110 or resting abnormally on the blade 110 even when the blade 110 is rotated or moved forward or backward rapidly.

Furthermore, the wafer guide 170 further comprises at least one wafer orientation guide pin 116 disposed on the plate 111. In the embodiment of FIGS. 2 and 5, one portion of the wafer guide step 112 is disposed at the end of one of the prongs of the plate 111, and a wafer orientation guide pin 116 is disposed at the end of the other prong of the plate 111 across from the wafer guide step 112. The wafer orientation guide pin 116 is designed for use with a wafer having a flat zone or a notch. More specifically, the wafer orientation guide pin 116 has a linear vertical surface conforming to the flat zone of a wafer or a pointed vertical surface that conforms to a notch in the edge of a wafer. The vertical surface of the wafer orientation guide pin 116 engages the wafer at the flat zone or in the notch of the wafer to orient the wafer such that the flat zone or notch of the wafer 102 faces in one direction. For example, the flat zone of the wafer 102 shown in FIG. 5 is oriented by the wafer orientation guide pin 116 at an angle of about 45° in a clockwise direction with respect to the direction in which the blade 110 moves forward. In addition, the wafer orientation adjustment guide pin 116 can have an inclined guide surface similar to that of the wafer guide step 112. Thus, in the case in which the wafer has a notch, the wafer orientation guide pin has a shape similar to that of a three-sided pyramid. In any case, the wafer orientation pin 116 and the wafer guide step 112 cooperate to guide and fix the wafer 102 in place on the plate 111 and thereby maintain the orientation of the wafer. Therefore, the wafer transfer robot 150 according to the present invention can transfer a pre-aligned wafer 102 without the wafer 102 sliding or rotating on the blade 110.

Furthermore, the wafer orientation guide pin 116 is rotatably supported by a shaft 118 at the end of the plate 111 of the blade 110. When the wafer is loaded onto the plate 111, the wafer orientation guide pin 116 is positioned such that the flat zone or notch of the wafer 102 can be located at basically an arbitrary position on the plate 111. Then, the wafer orientation guide pin 116 is rotated about the axis of the shaft 118 and brought into engagement with the wafer 102 so that the wafer 102 is fixed in position with the flat zone or notch of the wafer 102 facing in one direction.

For example, although not illustrated, a push lever is used to move the wafer orientation guide pin 16 into contact with the wafer 102 after the wafer has been loaded onto the plate 111 of the blade 110. With respect to the embodiment shown in FIG. 5, the push lever is used to rotate the wafer orientation guide pin 16 in a clockwise direction about the longitudinal axis of the shaft 118 and thereby bring the wafer orientation guide pin 116 into contact with the flat zone of the wafer 102. As a result, the wafer 102 is fixed in place as aligned.

At this time, the wafer orientation adjustment pin 116 pushes the wafer 102, at the flat zone (or notch as the case may be), against the wafer guide step 112 disposed across from the wafer orientation guide pin 116. Thus, the wafer 102 is grasped between the wafer orientation guide pin 116 and the wafer guide step 112. For this reason, external forces can not move the wafer 102 off of the plate 111 of the blade 110. Furthermore, the wafer transfer robot 150 according to the present invention can transfer the wafer at an inclination in contrast to the conventional wafer transfer robot which is only capable of transferring a wafer 102 horizontally.

According to the present invention as described above, the wafer transfer robot 150 can transfer a wafer without the wafer escaping from the blade 110 or becoming abnormally positioned on the blade 1100 even when the blade 110 is rapidly rotated or accelerated in forward or backward directions. Furthermore, the wafer transfer robot 105 can transfer a pre-aligned wafer without the alignment of the wafer changing during its transfer. Therefore, the present invention helps to maximize the production yield

Finally, the invention has been described in connection with the preferred embodiments thereof. However, it is to be understood that the present invention is not limited to the disclosed embodiments. On the contrary, modifications and alternative arrangements of the disclosed embodiments will be apparent to those of ordinary skill in the art. For example, although the wafer orientation guide pin 116 has been described as being disposed at the terminal end of the plate 111 of the blade 110, the present invention is not so limited. Rather, the wafer orientation guide pin 116 may be disposed at the edge of the plate 111 adjacent to the extenders 120. Therefore, various changes to the disclosed embodiments are seen to be within the true spirit and scope of the invention as defined by the appended claims.

What is claimed is:

1. A wafer transfer robot comprising:
a base;
at least one arm rotatably supported by the base at one side thereof, and the arm being extendable and retractable with respect to the base; and
a blade coupled to the other side of each said arm, the blade including a plate having an upper surface dedicated to support a wafer, and
a wafer guide disposed at the top of the plate, the wafer guide having at least one guide surface projecting above the upper surface of the plate and which is complimentary to both an arcuate edge and a flat zone or a notched portion of a wafer, whereby the wafer guide confines a wafer supported on the plate to an orientation in which a flat zone or notch of the wafer faces in a predetermined direction.

2. The wafer transfer robot according to claim 1, wherein the wafer guide comprises a wafer guide step having an arcuate vertical guide surface whose radius of curvature corresponds to that of a wafer, and a wafer orientation guide pin having a linear or pointed vertical guide surface that corresponds to a flat zone or notch of a wafer.

3. The wafer transfer robot according to claim 2, wherein the wafer orientation guide pin is supported at an edge of the plate so as to be rotatable about an axis extending perpendicular to the upper surface of the plate.

4. The wafer transfer robot according to claim 2, wherein the wafer orientation guide pin has a linear vertical guide surface that extends at an angle of about 45° in a clockwise direction with respect to a direction in which the blade is moved when the arm to which the blade is coupled is extended.

5. The wafer transfer robot according to claim 2, wherein the wafer orientation adjustment guide pin has an inclined guide surface extending down to the vertical guide surface thereof, wherein the inclined guide surface is inclined relative to the upper surface of the metal plate.

6. The wafer transfer robot according to claim 2, wherein the wafer guide step has an inclined guide surface extending down to the vertical guide surface thereof, wherein the inclined guide surface is inclined relative to the upper surface of the metal plate.

7. The wafer transfer robot according to claim 2, wherein the blade further comprises at least one pad at the upper surface of the plate on which a wafer is supported.

8. The wafer transfer robot according to claim 2, wherein each said at least one pad is of rubber.

9. The wafer transfer robot according to claim 7, wherein the plate has two prongs, and said at least one pad comprises two pads on each of the prongs.

10. Semiconductor device manufacturing equipment comprising:
at least one load-lock including a load-lock chamber sized to accommodate a wafer cassette;
a wafer alignment apparatus that aligns wafers, the wafer alignment apparatus having a chamber in which the alignment of wafers takes place;
at least one process apparatus that performs a semiconductor manufacturing process on a wafer, each said process apparatus having a process chamber, and a wafer support disposed within the process chamber, the wafer support dedicated to support a wafer while the wafer is being processed;
a transfer chamber to which each of the chambers of the load-lock, alignment and process apparatuses are commonly connected; and
a wafer transfer robot disposed in the transfer chamber and having a working envelope encompassing the load-lock and process apparatuses so as to transfer wafers between the load-lock and process apparatuses, the wafer transfer robot including a base,
at least one arm supported by the base at one side thereof, and
a blade coupled to the other side of each said arm, the blade including a plate having an upper surface dedicated to support a wafer, and
a wafer guide disposed at the top of the plate, the wafer guide having at least one guide surface projecting above the upper surface of the plate and which is complimentary to both an arcuate edge and a flat zone or a notched portion of a wafer, whereby the wafer guide confines a wafer supported on the plate to an orientation in which a flat zone or notch of the wafer faces in a predetermined direction.

11. The semiconductor device manufacturing equipment according to claim 10, wherein the wafer guide of the wafer transfer robot comprises a wafer guide step having an arcuate vertical guide surface whose radius of curvature corresponds to that of a wafer, and a wafer orientation guide pin having a linear or pointed vertical guide surface that corresponds to a flat zone or notch of a wafer.

12. The semiconductor device manufacturing equipment according to claim 11, wherein the wafer orientation guide pin is supported at an edge of the plate so as to be rotatable about an axis extending perpendicular to the upper surface of the plate.

13. The semiconductor device manufacturing equipment according to claim 11, wherein the wafer orientation guide pin has a linear vertical guide surface that extends at an angle of about 45° in a clockwise direction with respect to a direction in which the blade is moved when the arm to which the blade is coupled is extended.

14. The semiconductor device manufacturing equipment according to claim 11, wherein the wafer orientation adjustment guide pin has an inclined guide surface extending down to the vertical guide surface thereof, wherein the inclined guide surface is inclined relative to the upper surface of the metal plate.

15. The semiconductor device manufacturing equipment according to 11, wherein the wafer guide step has an inclined guide surface extending down to the vertical guide surface thereof, wherein the inclined guide surface is inclined relative to the upper surface of the metal plate.

16. The semiconductor device manufacturing equipment according to claim 11, wherein the blade further comprises at least one pad at the upper surface of the plate on which a wafer is supported.

17. The semiconductor device manufacturing equipment according to claim 16, wherein each said at least one pad is of rubber.

18. The semiconductor device manufacturing equipment according to claim 16, wherein the plate has two prongs, and said at least one pad comprises two pads on each of the prongs.
